(19) United States
(12) Patent Application Publication
(10) Pub. No.: US 2019/0393983 A1
(43) Pub. Date: Dec. 26, 2019

(54) COMMUNICATION APPARATUS AND SEQUENCE SELECTION METHOD

(71) Applicant: NTT DOCOMO, INC., Tokyo (JP)

(72) Inventors: Naoto Ookubo, Tokyo (JP); Satoshi Nagata, Tokyo (JP); Nobuhiko Miki, Takamatsu (JP)

(73) Assignee: NTT DOCOMO, INC., Tokyo (JP)

(21) Appl. No.: 16/481,372

(22) PCT Filed: Jan. 29, 2018
(86) PCT No.: PCT/JP2018/002727

§ 371 Date: Jul. 26, 2019

(30) Foreign Application Priority Data
Jan. 31, 2017 (JP) 2017-015959

(51) Int. Cl. H04L 1/00; H03M 13/13; H03M 13/00

(52) U.S. Cl. CPC H04L 1/0061; H03M 13/13; H03M 13/611; H04L 1/0046; H04L 1/0041

(57) ABSTRACT

A communication apparatus for use in a radio communication system, including: a reception unit configured to receive, from another communication apparatus, coded information to which a predetermined identifier is applied, decode the coded information to obtain a predetermined number of sequences that are candidates of a final decoding result, and perform a check by an error detection code using a plurality of identifiers for each of the predetermined number of sequences; and a sequence selection unit configured, if the check by the error detection code succeeds in a plurality of sequences by the reception unit, to select a sequence of the highest likelihood from the plurality of sequences as the final decoding result.

### TECHNICAL FIELD

The present invention relates to a communication apparatus used as a user apparatus or a base station in a radio communication system.

### BACKGROUND ART

In 3rd Generation Partnership Project (3GPP), study of a radio communication scheme called 5G has been progressing for realizing further increase of system capacity, further increase of data transmission speed, and lower delay in radio sections and the like. In 5G, in order to satisfy the requirement to make the delay of the radio section equal to or less than lms while realizing throughput equal to or greater than 10 Gbps, studies of various radio techniques are progressing. Since there is a high possibility in that radio techniques different from LTE are adopted in 5G, a radio network supporting 5G is called a new radio network (NR: New Radio) so that 5G is differentiated from a radio network supporting LTE in 3GPP.

In 5G, three use cases of extended mobile broadband (eMBB), massive machine type communication (mMTC), ultra reliability and low latency communication (URLLC) are mainly assumed.

For example, in eMBB, higher speed and larger capacity are required. On the other hand, in mMTC, connection of a large number of terminals and low consumption power are required, and in URLLC, high reliability and low delay are required. In order to realize these requirements, it is necessary to satisfy these requirements even in channel coding indispensable in mobile communications.

As a candidate that can realize the above-mentioned requirements, there is Polar code (non-patent document 1). The Polar code is an error correction code that makes it possible to realize characteristics asymptotic to Shannon limit based on the idea of channel polarization. Also, as a decoding method for the Polar code, by using a simple successive cancellation decoding method (SCD: Successive Cancellation Decoding), excellent characteristics with low computational complexity and low power consumption can be realized. Also, as methods for decoding of Polar code, there are known a successive cancellation list decoding method (SCLD: Successive Cancellation List Decoding) that improves characteristics of SCD, and a successive cancelation list decoding method (CRC-aided SCLD) using CRC (Cyclic Redundancy Check) in which characteristics are further improved (non-patent document 2). In the CRC-aided SCLD, a plurality of sequences (bit sequences) of high likelihood are obtained, so that one sequence by which CRC decision succeeds is selected from them as a final decoding result.

### PRIOR ART DOCUMENT

### Non-Patent Document

[Non-Patent Document 1] E. Arikan, “Channel Polarization: A Method for Constructing Capacity-Achieving Codes for Symmetric Binary-Input Memoryless Channels, ” IEEE Trans. Inf. Theory, vol.55, no.7, pp.3051-3073, July 2009.

[Non-Patent Document 2] Nobuhiko MIKI and Satoshi NAGATA, “Polar Codes for Mobile Communication Systems and Standardization Activity”, TECHNICAL REPORT OF IEICE, vol.116, no. 396, RCS2016-271, pp.205-210, January 2017

[Non-Patent Document 3] 3GPP TS 36.321 V14.1.0 (2016-12)

### SUMMARY OF INVENTION

### Problem to be Solved By the Invention

In NR, it is assumed to apply the Polar code for a downlink control channel. Also, in NR, similarly to a transmission and reception method of a downlink control channel in the existing LTE, it is assumed that a base station adds CRC (“CRC” may be used as meaning a value for checking, hereinafter) to downlink control information, encodes information obtained by masking the CRC with an RNTI (Radio Network Temporary Identifier), and transmits the information to the user apparatus. In decoding processing of the information, the user apparatus that receives the information makes a decision using the CRC that is unmasked by an RNTI that the user apparatus itself holds, so that the use apparatus determines whether the received information is information addressed to the user apparatus itself. Also, in general, there are a plurality of RNTIs, so that the user apparatus can determine a channel and the like related to the received downlink control information by the RNTI that is used when the CRC decision succeeds.

As described above, in the CRC-aided SCLD that is a decoding method of the Polar code, a plurality of sequences of high likelihood are obtained, and one sequence for which CRC decision succeeds is selected from them as a final decoding result. However, when the user apparatus performs decoding processing using a plurality of RNTIs, it is assumed that CRC decision may succeed for a plurality of sequences using a plurality of different RNTIs. In such a case, it is unclear for the user apparatus which sequence to select from a plurality of sequences for which CRC decision succeeds as a final decoding result. The above-mentioned problem is not limitedly applied to downlink communication from the base station to the user apparatus, but, the problem may also arise in uplink communication from the user apparatus to the base station, and also in sitelink communication between user apparatuses. Apparatuses such as the user apparatus and the base station and the like are collectively called a communication apparatus.

The present invention is contrived in view of the above-mentioned point, and an object of the present invention is to provide a technique for making it possible that a communication apparatus properly selects one sequence when a plurality of sequences are obtained by checking by an error correction code, in a technique in which the communication apparatus selects, based on checking by an error correction code, one sequence from a plurality of sequences obtained by decoding coded information to which a predetermined identifier is applied.

### Means for Solving the Problem

According to a disclosed technique, there is provided a communication apparatus for use in a radio communication system, including:

a reception unit configured to receive, from another communication apparatus, coded information to which a predetermined identifier is applied, decode the coded information to obtain a predetermined number of sequences that are candidates of a final decoding result, and perform a check by an error detection code using a plurality of identifiers for each of the predetermined number of sequences; and

a sequence selection unit configured, if the check by the error detection code succeeds in a plurality of sequences by the reception unit, to select a sequence of the highest likelihood from the plurality of sequences as the final decoding result.

### Advantage of the Invention

According to a disclosed technique, there is provided a technique for making it possible that a communication apparatus properly selects one sequence when a plurality of sequences are obtained by checking by an error correction code, in a technique in which the communication apparatus selects, based on checking by an error correction code, one sequence from a plurality of sequences obtained by decoding coded information to which a predetermined identifier is applied.

### BRIEF DESCRIPTION OF DRAWINGS

FIG. 1 is a block diagram of a radio communication system in an embodiment of the present invention;

FIG. 2 is a diagram for explaining an outline of a successive cancelation list decoding method;

FIG. 3 is a diagram for explaining a method of successive cancelation decoding using CRC;

FIG. 4 is a diagram for explaining operation of transmission and reception of downlink control information by a downlink control channel;

FIG. 5 is a diagram showing an example of types of RNTIs;

FIG. 6 is a diagram for explaining a case in which CRC is OK for a plurality of RNTIs;

FIG. 7 is a diagram for explaining a whole operation example;

FIG. 8 is a diagram for explaining a whole operation example;

FIG. 9 is a diagram for explaining a selection method example 1;

FIG. 10 is an example of priorities of RNTIs;

FIG. 11 is a diagram showing signaling of priority notification method examples 1 and 2;

FIG. 12 is a diagram showing an example of a list of priorities;

FIG. 13 is a diagram showing an example of functional configuration of a user apparatus 10;

FIG. 14 is a diagram showing an example of functional configuration of a base station 20;

FIG. 15 is a diagram showing an example of hardware configuration of the user apparatus 10 and the base station 20.

### EMBODIMENTS OF THE INVENTION

Hereinafter, an embodiment of the present invention (present embodiment) will be described with reference to the accompanying drawings. The embodiments described below are only examples and embodiments to which the present invention is applied are not limited to the following embodiments.

In actual operation of the radio communication system of the present embodiment, existing techniques can be appropriately used. The existing techniques are techniques of LTE, for example, but not limited to LTE.

In the following embodiment described below, terms PDCCH, DCI, RNTI, RRC, SIB, and the like which are used in the existing LTE are used, but these terms are only used in convenience of description, signals or functions and the like similar to signals or functions indicated by the terms may be referred to as other names.

Also, in the present embodiment, the Polar code is used for encoding, and the CRC-aided SCLD is used for decoding, however, these are merely examples. The present invention can be applied to the whole coding/decoding methods for obtaining a plurality of sequences that are candidates of a final result in decoding and selecting one sequence from the plurality of sequences. For example, the present invention can be applied to a case using tail-biting convolutional code in encoding. When using the tail-biting convolutional code, List Viterbi decoding can be used in decoding for example.

Also, in the present embodiment, CRC is used as an example of the error correction code, however, error correction code to which the present invention can apply is not limited to CRC. Also, in the present embodiment, the target of encoding/decoding is control information, however, the present invention can be applied to information other than control information. Also, in the present embodiment, RNTI is used as an identifier, however, the present invention can be applied to identified other than RNTI.

Also, in the present embodiment, downlink communication is shown as an example, however, the present invention can be applied similarly to uplink communication and sidelink communication. For example, in uplink communication, the user apparatus may have the function for generating and transmitting coded information in the base station 20 described below, and the base station may have the function of decoding and sequence selection in the user apparatus 10 described below. Also, in sidelink communication, the user apparatus may have the function for generating and transmitting coded information in the base station 20 described below, and another user apparatus may have the function of decoding and sequence selection in the user apparatus 10 described below.

(System Whole Configuration)

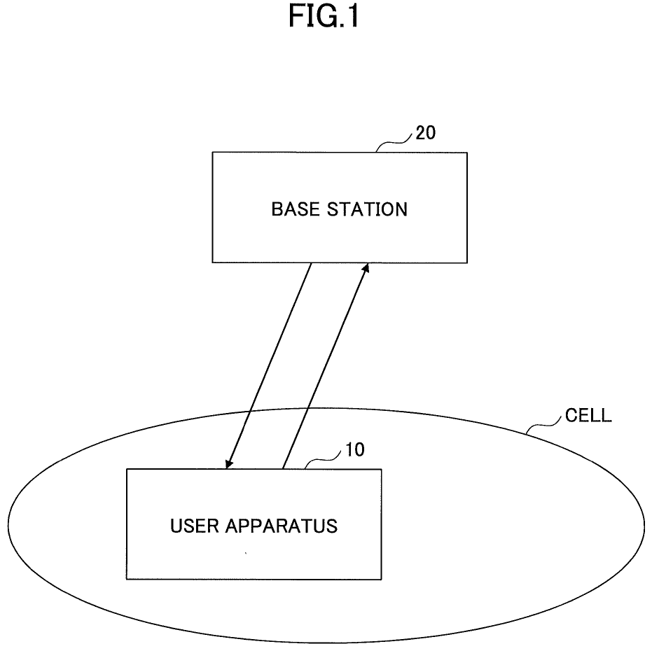

FIG. 1 shows a block diagram of a radio communication system of the present embodiment. As shown in FIG. 1, the radio communication system of the present embodiment includes a user apparatus 10 and a base station 20. FIG. 1 shows one user apparatus 10 and one base station 20, but, this is merely an example, and there may be a plurality of user apparatuses 10 and a plurality of base stations 20.

The user apparatus 10 is a communication apparatus having a radio communication function such as a smart phone, a mobile phone, a tablet, an wearable terminal, and a communication module for M2M (Machine-to-Machine) and the like. The user apparatus 10 connects to the base station 20 by radio, and uses various communication services provided by the radio communication system. The base station 20 is a communication apparatus that communicates by radio with the user apparatus 10. In the present embodiment, the duplex scheme may be a TDD (Time Division Duplex) or may be an FDD (Frequency Division Duplex) scheme.

(Basic Operation Example)

<On CRC-Aided SCLD>

In the present embodiment, the base station 20 encodes information that is obtained by adding CRC to downlink control information (DCI) by using the Polar code so as to transmit the coded information using a PDCCH (Physical Downlink Control Channel). The user apparatus 10 decodes information encoded by the Polar code by CRC-aided SCLD (successive cancellation list decoding method using CRC). In the following, first, decoding operation in CRC-aided SCLD is described.

As a simple decoding method of the Polar code, the SCD (successive cancellation decoding) is known. However, in the SCD, since the processing is performed sequentially, it is known that characteristics deterioration due to error propagation occurs when a decoded bit in the middle is erroneous. That is, in the SCD, when decoding an i-th bit, since only up to i-th bit is considered (after the (i+1) bit is not considered), the final decoding result may not be the maximum likelihood sequence. As a method for solving the characteristics deterioration due to this error propagation, SCLD on which CRC-aided SCLD is based is known.

In the SCLD, when decoding the i-th bit, L sequences of high likelihood are regarded as survived paths (L is referred to as a list size), and only the maximum likelihood sequence is output as a decoding result when decoding the last N-th bit. Accordingly, characteristics deterioration in the SCD can be compensated.

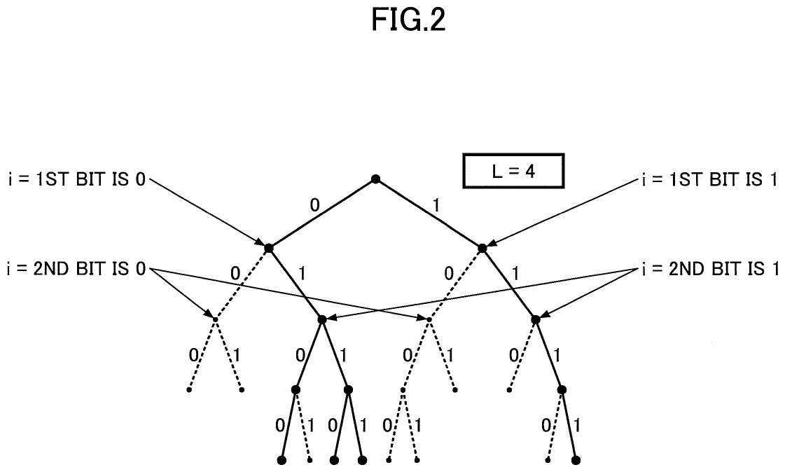

FIG. 2 is a diagram showing an outline of the SCLD in the case of L=4. When decoding is performed in the order from the i=1st bit, there are sequence candidate patterns of i-th power of two, but only L sequences having a high likelihood cumulative value are determined as survivors each time when a bit is decoded. The cumulative value of likelihood is, for example, a sum of likelihood of each bit. In the example of FIG. 2, it is shown that 4 sequences of “0100”, “110”, “0111”, and “1111” are obtained. In the following, “likelihood” for sequence means the above-mentioned cumulative vale of likelihood.

In the SCLD, L sequences finally survive, and the most likely sequence among them is determined as a final decoded sequence. However, actually, there is a possibility in that the finally determined sequence is erroneous and a correct sequence remains in the remaining L-1 sequences.

Thus, like the radio communication system of the present embodiment, in the case in which a bit sequence of CRC is added to an information bit sequence (downlink information), by performing CRC decision for the survived L sequences, it is possible to select a sequence whose CRC decision is OK from among the L most likely sequences. Accordingly, the characteristics can be largely improved compared to the SCLD in which CRC is not used.

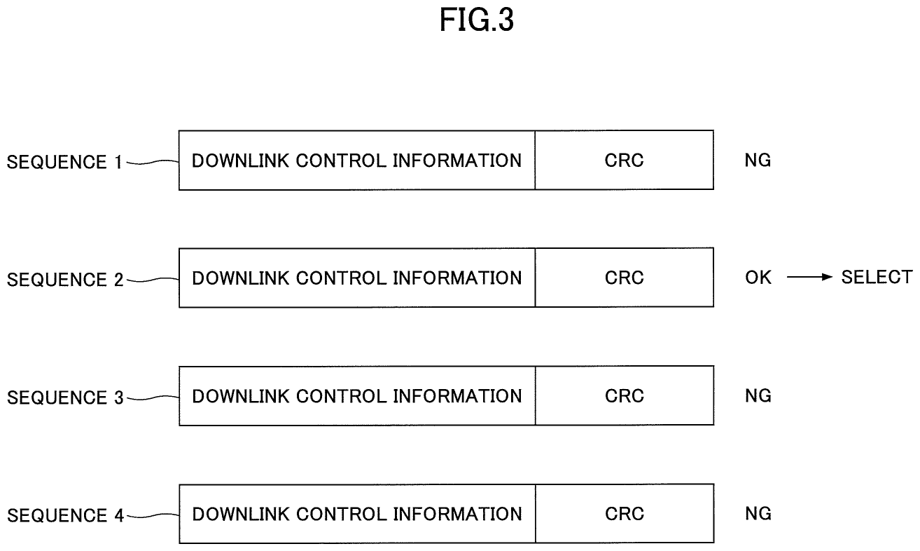

FIG. 3 shows a simple example. For example, the user apparatus 10 performs sequential decoding processing for each bit on the coded information received by the PDCCH from the base station 20, so that the user apparatus 10 obtains four sequences 1-4 having high likelihood as shown in FIG. 3. Note that it is assumed that unmasking by an RNTI has completed in order to clarify the explanation about CRC-aided SCLD. If the CRC decision for the sequence 2 succeeds, for example, by performing the CRC decision for each sequence, the user apparatus 10 selects the sequence 2 as the final decoding result. Then, for example, the use apparatus 10 executes processing (example: reception of data channel) after that according to downlink control information included in the sequence 2, for example. <On RNTI Masking/Unmasking>

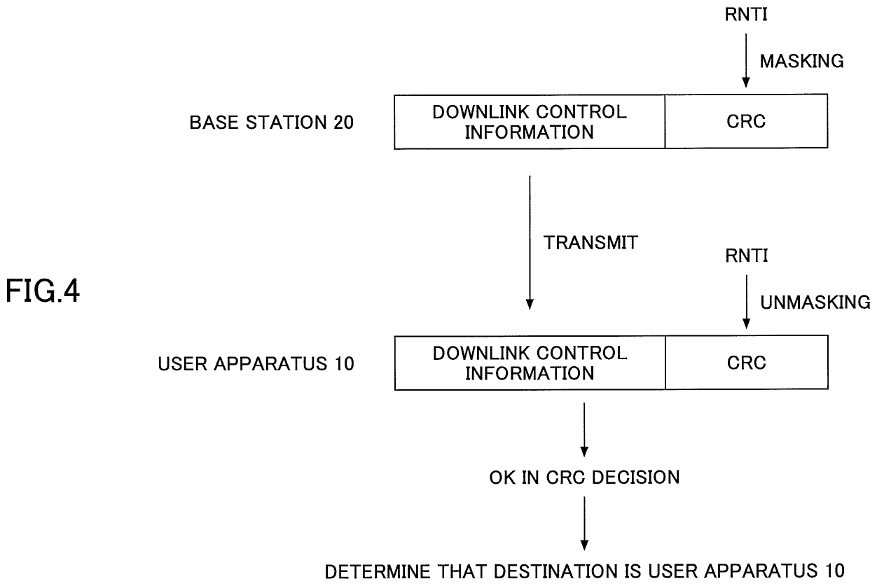

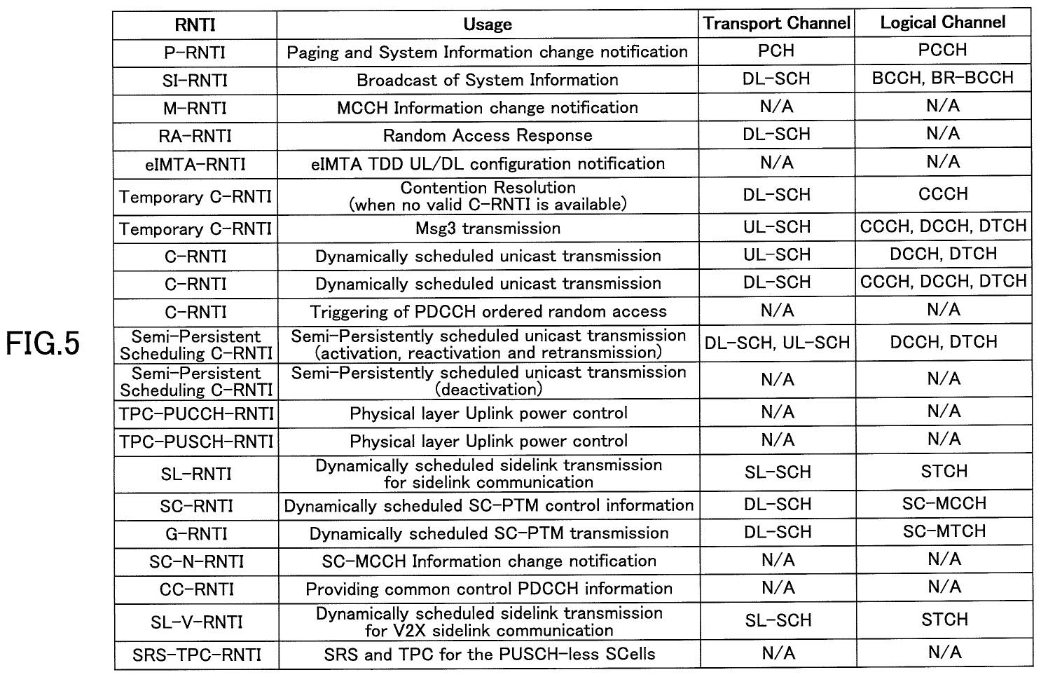

As shown in FIG. 4, the base station 20 according to the present embodiment adds a CRC to downlink control information (which may be referred to as DCI, PDCCH payload) like the existing LTE, and masks the CRC with an RNTI. More specifically, for example, exclusive OR of the bits of the CRC and the corresponding bits of the RNTI becomes the value after masking of the bits. Note that the RNTI is an identifier for identifying a user apparatus and/or a channel, and there are various kinds of RNTIs. The base station 20 selects an RNTI according to the current operation, and uses it for masking. As an example, FIG. 5 shows types of RNTIs in the existing LTE (excerpt from the non-patent document 3).

For example C-RNTI is an RNTI for receiving user data, SPS (Semi Persistent Scheduling)—RNTI is an RNTI for receiving data in SPS, P-RNTI is an RNTI for receiving a paging, and SI-RNTI is an RNTI for receiving broadcast information (system information that is broadcasted).

The “downlink control information+CRC (+RNTI)” prepared as mentioned above is encoded and transmitted to the user apparatus 10 by a PDCCH.

The user apparats 10 tries to decode downlink control information by performing blind decoding in a search space. As shown in FIG. 4, for example, the user apparatus 10 determines that the downlink control information is downlink control information addressed to the user apparatus 10 when CRC decision using a CRC obtained by unmasking with an RNTI (example: C-RNTI) that the user apparatus 10 has is OK, and uses the downlink control information. Also, the user apparatus 10 can determine a type of a channel (data) received by assignment information of the downlink control information according to the type of the RNTI by which CRC decision succeeds. That is, the user apparatus 10 can specify the RNTI that succeeds in the CRC decision to be the RNTI used for masking the CRC in the base station 20.

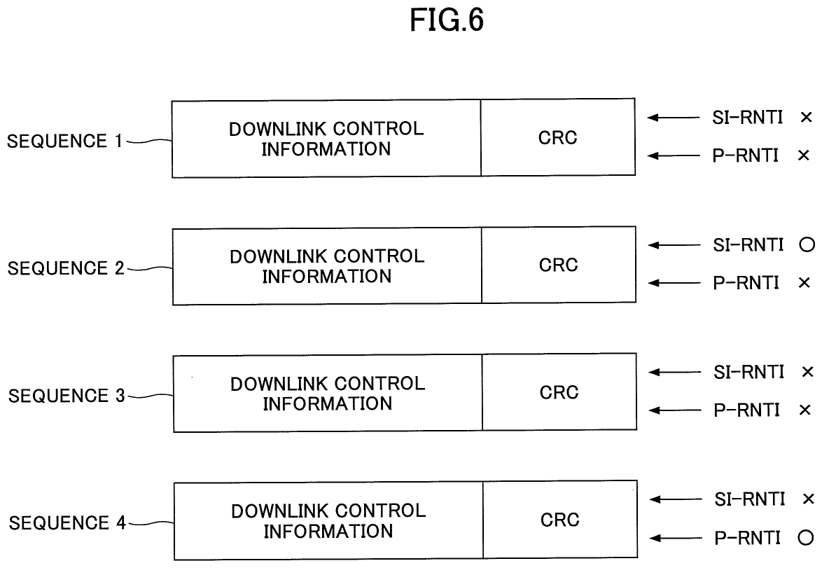

As described before, in the present embodiment, the user apparatus 10 decodes the coded information received from the base station 20 using the CRC-aided SCLD. Therefore, the user apparatus 10 performs the decoding processing in the search space where the downlink control information is supposed to be present, so that for example, as shown in FIG. 6, the user apparatus 10 obtains four sequences (when L=4) of high likelihood first.

For each obtained sequence, the user apparatus 10 performs unmasking (exclusive OR similar to masking) on CRC (bit sequence corresponding to the position of CRC) using each RNTI that the user apparatus 10 itself has, and performs CRC decision using a CRC obtained by unmasking for each RNTI used for unmasking. As a simple example, FIG. 6 shows an example that the user apparatus 10 performs unmasking by each of SI-RNTI and P-RNTI.

The base station 20 adds one CRC to downlink control information and masks it with one RNTI. Thus, generally, it can be considered that only one sequence succeeds in CRC decision by unmasking with a correct RNTI. However, in the case where unmasking is performed using a plurality of RNTIs to perform CRC decision in the user apparatus 10, depending on the combination of downlink control information, CRC, and RNTI, CRC decision may succeed in a plurality of sequences unmasked with different RNTIs.

FIG. 6 shows an example of such a case. In sequence 2, CRC decision succeeds when using SI-RNTI, further, in sequence 4, CRC decision succeeds when using P-RNTI. Note that, in the present embodiment, it is assumed that CRC decision does not succeed for a plurality of different sequences in the same RNTI, however, even if such a situation occurs, for example, one sequence can be selected by the after-mentioned selection method example 1. That is, in the example of FIG. 6, for example, one sequence can be selected in the case in which CRC decision succeeds when using SI-RNTI in sequence 2 and further CRC decision succeeds when using SI-RNTI in sequence 3.

In the present embodiment, as shown in FIG. 6, even when CRC decision succeeds in a plurality of sequences to which different RNTIs are applied, it is possible to appropriately select one sequence (and applied RNTI) as the final decoding result. In the following, the operation including this selection operation is described in more detail.

(Whole Operation Example of Radio Communication System)

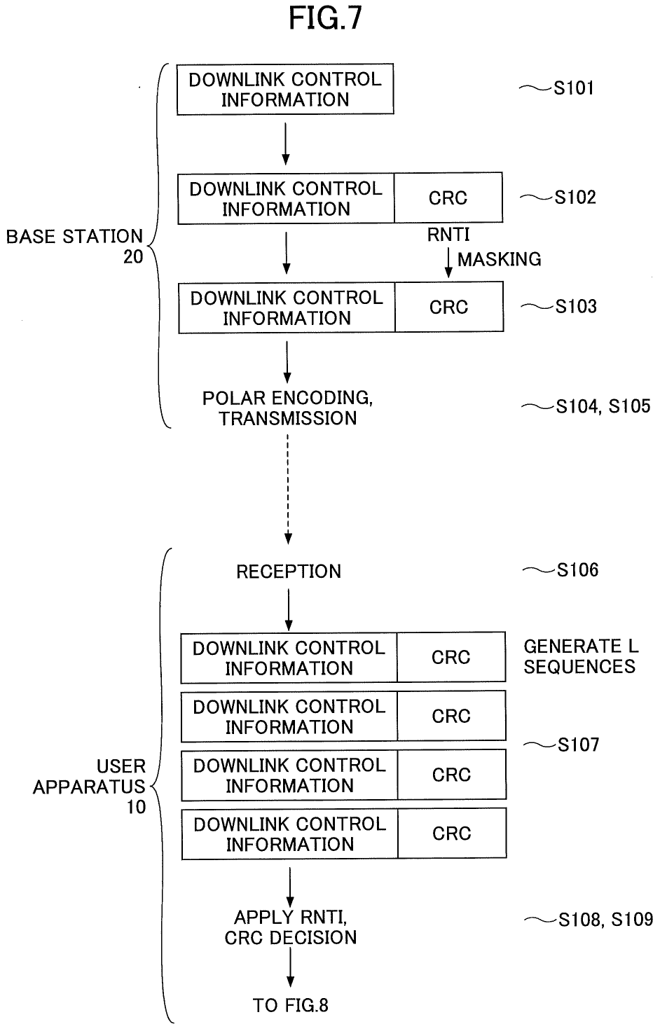

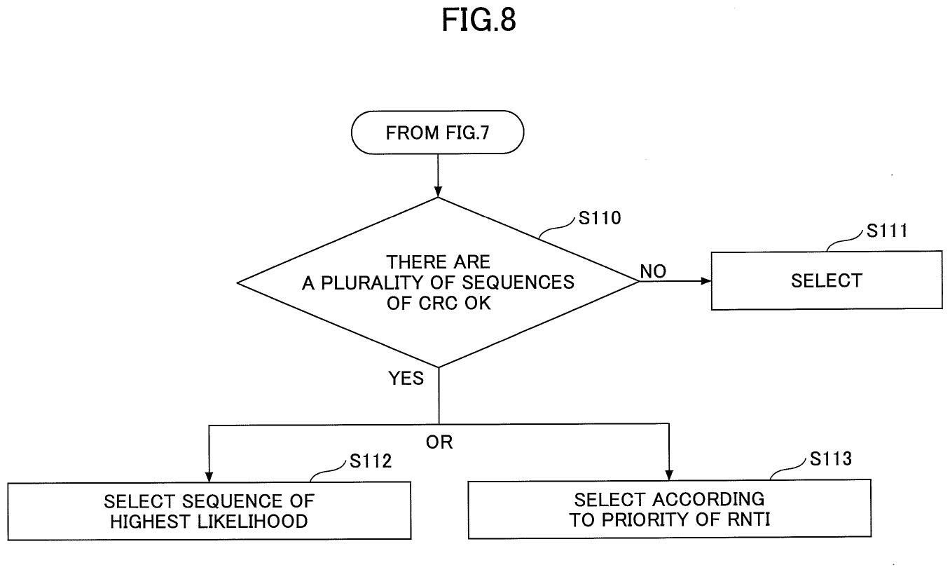

FIGS. 7 and 8 are schematic diagrams for explaining the overall operation example of the radio communication system. The base station 20 generates downlink control information addressed to the user apparatus 10 (step S101), and adds CRC to the downlink control information (step S102). The base station 20 masks the CRC by using an RNTI (step S103). The base station 20 encodes a bit sequence (using Polar code) of “downlink control information +masked RNTI” (step S104) to transmit the coded information by radio (step S105).

The use apparatus 10 receives coded information (step S106) and executes decoding processing. In the present embodiment, since decoding processing is performed by CRC-aided SCLD, first, the user apparatus 10 generates L sequences (FIG. 7 shows an example of four sequences) that are candidates of the final decoding result (step S107).

As described with reference to FIG. 6, the user apparatus 10 performs unmasking for each sequence using each of a plurality of holding RNTIs (step S108) and performs CRC decision (step S109). Note that, which RNTI to use depends on the current timing etc. For example, if the current time is not in a time window for receiving a random access response, RA-RNTI may not be used.

In step S110 of FIG. 8, if a plurality of sequences do not succeed in CRC decision (that is, if only one sequence succeeds in CRC decision), the user apparatus 10 determines the sequence to be the final decoding result and selects it (step S111). The user apparatus 10 determines a type of channel or data to be subsequently received, for example, by the RNTI that succeeds in the CRC decision.

On the other hand, in step S110, if there are a plurality of sequences that succeed in CRC decision, the user apparatus 10 selects, as the final decoding result, a sequence of the highest likelihood (accumulated metric value) from among the plurality sequences (step S112). Alternatively, the use apparatus 10 selects, as the final decoding result, a sequence to which an RNTI of the highest priority is applied in unmasking (step S113).

The method of selecting the sequence with the highest likelihood in step S112 is regarded as a selection method example 1 and the method of selecting the sequence to which the RNTI of the highest priority is applied in step S113 is regarded as a selection method example 2.

Which one of the selection method example 1 or the selection method example 2 to execute may be fixed in advance, for example, or may be designated from the base station 20 to the user apparatus 10 by RRC signaling or broadcast information.

Hereinafter, the selection method example 1 and the selection method example 2 are more specifically described.

(Selection Method Example 1)

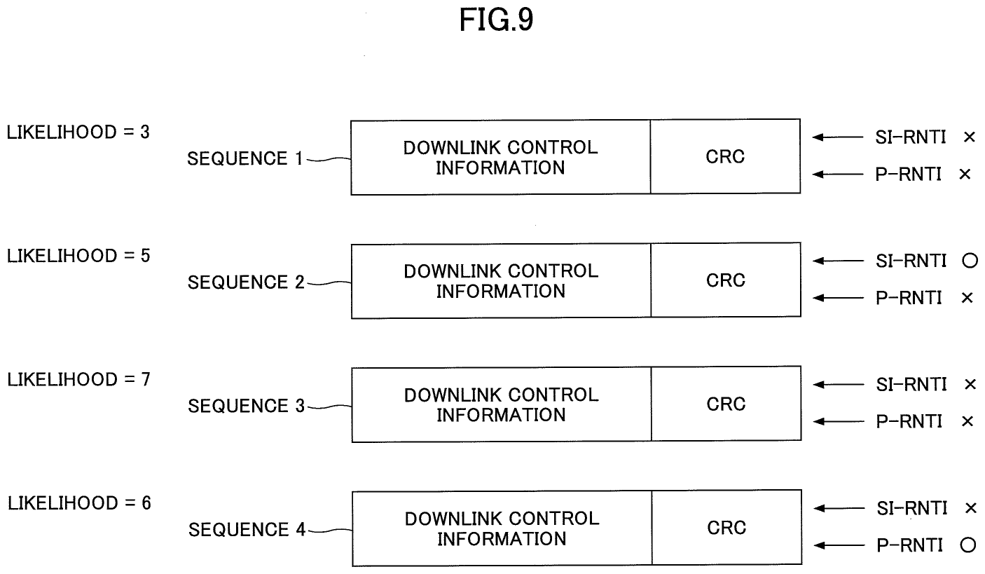

FIG. 9 is a diagram for more specifically explaining the selection method example 1. FIG. 9 shows a case where L=4, and SI-RNTI and P-RNTI are used as a plurality of RNTIs. As shown in FIG. 9, the user apparatus 10 acquires four sequences 1 to 4 by performing decoding processing on the encoded information received from the base station 20. Also, as shown in FIG. 9, likelihoods of each sequence are obtained, so that the user apparatus 10 holds the likelihoods with each sequence. Note that greater the value is, the higher the likelihood is, in this example.

The user apparatus 10 unmasks CRC using each of SI-RNTI and P-RNTI for each sequence so as to execute CRC decision. As a result, CRC decision succeeds for sequence 2 in which unmasking is performed by SI-RNTI, and for sequence 4 in which unmasking is performed by P-RNTI.

In this case, in the selection method example 1, the user apparatus 10 compares likelihoods between the sequence 2 and the sequence 4 to select the sequence 4 with higher likelihood as the final decoding result, and the user apparatus 10 determines P-RNTI that is used for unmasking when CRC decision succeeds to be a correct RNTI (RNTI that is used for masking in the base station 20).

According to the selection method example 1, the user apparatus 10 can correctly receive the downlink control information transmitted from the base station 20 and can execute an operation based on the downlink control information. This makes it possible to increase the stability of the operation of the system. Further, in the selection method example 1, the signaling amount can be reduced as compared with the method of signaling a priority of an RNTI in the selection method example 2.

(Selection Method Example 2)

The selection method example 2 is also described first using the example shown in FIG. 9. Here, it is assumed that the priority of SI-RNTI is higher than the priority of P-RNTI. The priority of this embodiment can be represented by a numerical value (positive integer), and the lower the numerical value is, the higher the priority is. Of course, instead of this, it may be determined that the priority is higher as the numerical value is larger. Also, priorities may be expressed in an order in which RNTIs are arranged instead of expressing the priorities as numerical values.

For example, when a plurality of RNTIs are represented by a one-dimensional list (array), the top of the list has the highest priority, and the priority can be expressed as an order of arrangement of elements (RNTIs) in the list. Further, a numerical value indicating an order in which RNTIs are arranged may be regarded as a numerical value representing a priority.

As shown in FIG. 9, CRC decision succeeds for sequence 2 in which unmasking is performed by SI-RNTI, and for sequence 4 in which unmasking is performed by P-RNTI. In the selection method example 2, the user apparatus 10 selects, as the final decoding result, the sequence 2 for which CRC decision succeeds using SI-RNTI with higher priority, and determines that SI-RNTI is a correct RNTI (RNTI that is used for masking in the base station 20).

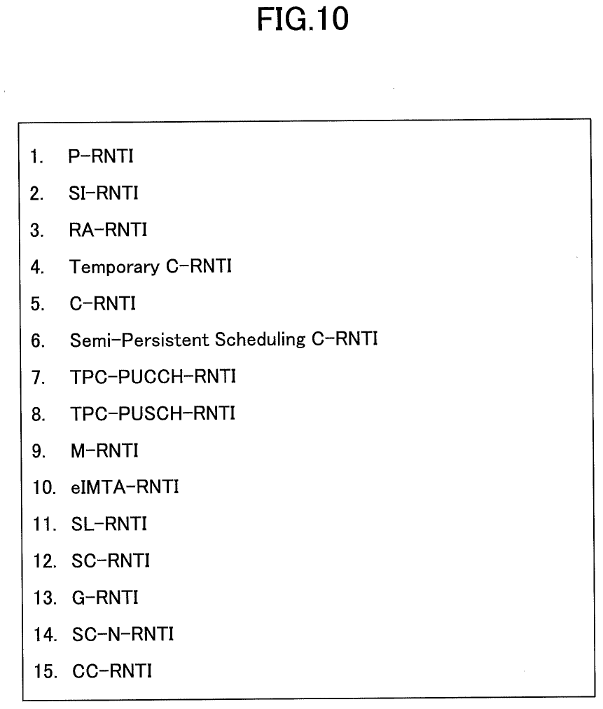

FIG. 10 shows an example of priorities of RNTIs in the selection method example 2. In the example shown in FIG. 10, RNTIs are arranged from the top in an order of priority levels. That is, the priority of P-RNTI is the highest, and the priority of SI-RNTI is next higher.

In priorities shown in FIG. 10, for example, when CRC decision succeeds for RNTIs of the paging channel (P-RNTI) and the broadcast channel (SI-RNTI), the paging channel is prioritized. Also, when CRC decision succeeds for the PDSCH (C-RNTI) for user data and TPC-PUCCH-RNTI, the user data channel is prioritized.

(Selection Method 2: On Setting Method of Priority)

<Presetting>

For example, a priority of an RNTI is predetermined fixedly, and the user apparatus 10 and the base station 20 respectively hold the information of the priority as configuration information. Note that the priority of the RNTI may not be defined for all RNTIs for use. For example, the user apparatus 10 determines that a priority of an RNTI for which the priority is not defined is lower than a priority of a RNTI for which the priority is defined. Also, for example, when the user apparatus 10 detects CRC decision OK for a plurality of sequences to which a plurality of RNTIs for which priorities are not determined are applied, the user apparatus 10 applies the selection method example 1 to select the highest likelihood sequence.

Instead of presetting as described above, a priority of an RNTI may be notified from the base station 20 to the user apparatus 10 by signaling as described below. As methods of performing such notification, there are a priority notification method example 1 and a priority notification method example 2.

<Priority Notification Method Example 1>

In the priority notification method example 1, as shown in step 5201 in FIG. 11, the base station 20 transmits information of priority (Cell specific) common to the cell of the base station 20 by broadcast information (example: SIB or MIB).

For example, in the case where a service provider has a policy to cause the user apparatus in the cell to receive a paging as reliably as possible, the base station 20 transmits information of priority in which priority of P-RNTI is set high by broadcast information.

<Priority Notification Method Example 2>

In the priority notification method example 2, as shown in step S301 of FIG. 11, the base station 20 individually notifies each user apparatus of information of priority by UE specific (UE specific) RRC signaling (example: RRC CONNECTION RECONFIGURATION).

For example, when the base station 20 grasps that the user apparatus has capability of performing sidelink communication, or that the user apparatus desires to perform sidelink communication based on notification from the user apparatus, the base station 20 notifies the user apparatus of information of priority in which priority of SL-RNTI is set high by RRC signaling.

In both cases of the priority notification method example 1 and the priority notification method example 2, the base station 20 may not notify of priorities of all RNTIs for use. For example, the user apparatus 10 determines that a priority of an RNTI without notification of priority is lower than a priority of an RNTI for which priority is notified. Also, for example, when the user apparatus 10 detects CRC decision OK for a plurality of sequences to which a plurality of RNTIs for which priority is not notified are applied, the user apparatus 10 applies the selection method example 1 to select a sequence of the highest likelihood.

<Example of Notification Content>

In the above-mentioned priority notification method example 1 and the priority notification method example 2, the information of priority of RNTI notified from the base station 20 to the user apparatus 10 may be any information as long as priority of RNTI can be grasped by the information.

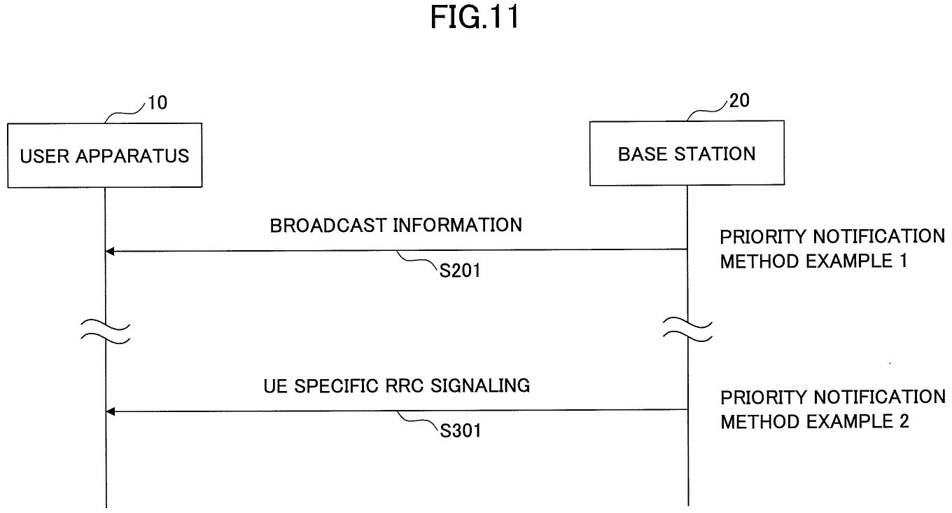

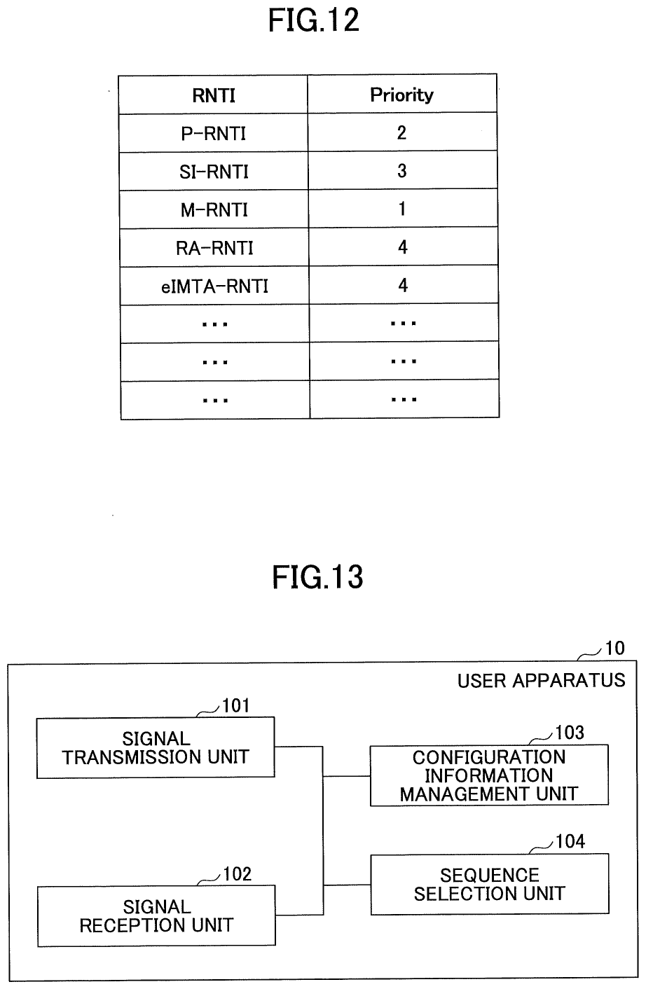

For example, the base station 20 notifies the user apparatus 10 of a list of priorities of RNTIs shown in FIG. 12. The example shown in FIG. 12 is a list including, for each RNTI, information indicating an RNTI and a numerical value indicating a priority of the RNTI. There may be a case in which priorities are the same between RNTIs. In this case, if the user apparatus 10 detects CRC decision OK for a plurality of sequences to which RNTIs having the same priority are applied, the user apparatus 10 applies the selection method example 1 to select a sequence of the highest likelihood.

The base station 20 may notify the user apparatus 10 of a list, not having the numerical values of priorities shown in FIG. 12, in which RNTIs are arranged in an order of priority.

Also, instead of notifying of the list as mentioned above, the base station 20 may notify the user apparatus 10 of a priority level for each RNTI. In this case, for example, the base station 20 notifies the user apparatus 10 of information of combination of RNTI and priority level such as {P-RNTI, Priority level=1} for each RNTI. Also, as for an RNTI (example: C-RNTI) assigned from the base station 20 to the user apparatus 10, the base station 20 may include information of priority of the RNTI in a message used for transmitting the RNTI to the user apparatus 10.

According to the selection method example 2 described above, the user apparatus 10 can receive a channel of high priority with higher reliability. Also, since priority of RNTIs can be controlled in the base station 20 side, it becomes possible to perform control according to a policy of a service provider.

(Apparatus Configuration)

An example of the functional configurations of the user apparatus 10 and the base station 20 performing the above-mentioned operations described so far are described below.

<User Apparatus>

FIG. 13 is a diagram illustrating an example of a functional configuration of the user apparatus 10. As illustrated in FIG. 13, the user apparatus 10 includes a signal transmission unit 101, a signal reception unit 102, a configuration information management unit 103, and a sequence selection unit 104. The functional configuration illustrated in FIG. 13 is only an example. Functional subdivision and names of the functional units are not particularly limited as long as the operations associated with the embodiment can be performed.

The signal transmission unit 101 generates a transmitting signal from transmission data to transmit the transmission signal by radio. The signal reception unit 102 receives by radio various signals, and obtains a signal of upper layer from a received signal of the physical layer.

The configuration information management unit 103 stores various configuration information received from the base station 20 by the signal reception unit 102. Content of the configuration information is, for example, information of priority of RNTI described so far. Also, the configuration information management unit 103 stores a plurality of RNTIs for use in the user apparatus 10. The sequence selection unit 104 executes processing of selection of sequences described in the present embodiment. Note that the sequence selection unit 104 may be included in the signal reception unit 102.

For example, the signal reception unit 102 receives, from the base station 20, coded information to which a predetermined identifier is applied, decodes the coded information to obtain a predetermined number of sequences that are candidates of a final decoding result, and performs a check by an error detection code using a plurality of identifiers for each of the predetermined number of sequences, and if the check by the error detection code succeeds in a plurality of sequences by the signal reception unit 102, the sequence selection unit 104 can select a sequence of the highest likelihood from the plurality of sequences as the final decoding result.

The signal reception unit 102 receives, from the base station 20, coded information to which a predetermined identifier is applied, decodes the coded information to obtain a predetermined number of sequences that are candidates of a final decoding result, and performs a check by an error detection code using a plurality of identifiers for each of the predetermined number of sequences, and if the check by the error detection code succeeds in a plurality of sequences by the signal reception unit 102, the sequence selection unit 104 may select, as the final decoding result, a sequence in which priority of an identifier used when the check by the error detection code succeeds is the highest from the plurality of sequences.

When priorities of identifiers used when the check by the error detection code succeeds are the same among the plurality of sequences, the sequence selection unit 104 may select a sequence of the highest likelihood from the plurality of sequences as the final decoding result.

Also, the sequence selection unit 104 determines an identifier used when the check by the error detection code succeeds for a sequence selected as the final decoding result to be the predetermined identifier applied in the base station 20.

<Base Station 20>

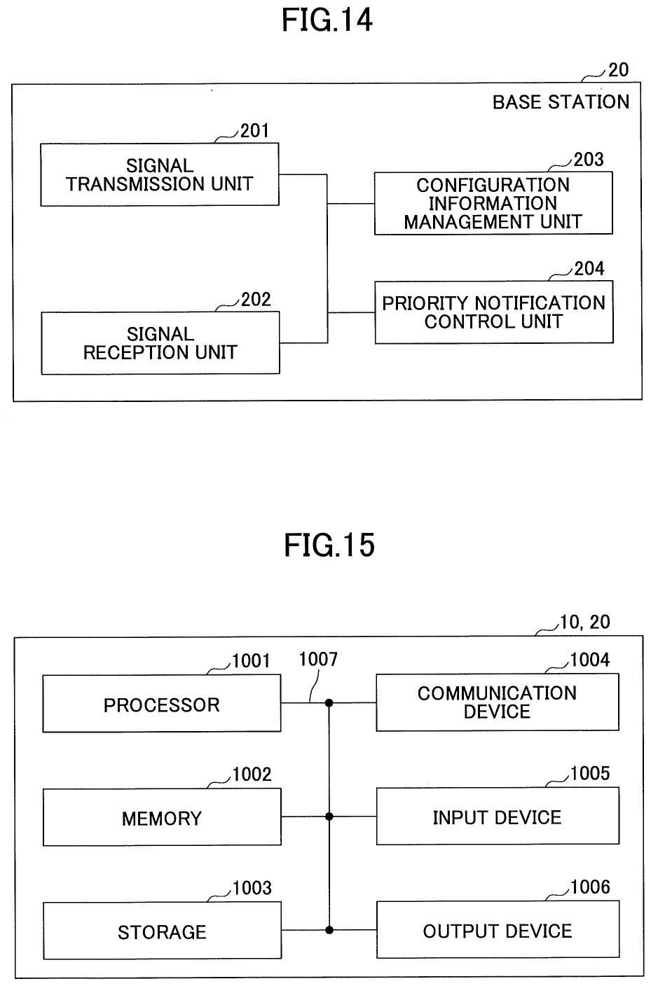

FIG. 14 is a diagram illustrating an example of a functional configuration of the base station 20. As illustrated in FIG. 14, the base station 20 includes a signal transmission unit 201, a signal reception unit 202, a configuration information management unit 203 and a priority notification control unit 204. The functional configuration illustrated in FIG. 14 is only an example. Functional subdivision and names of the functional units are not particularly limited as long as the operations associated with the embodiment can be performed.

The signal transmission unit 201 includes a function configured to generate a signal to be transmitted to the user apparatus 10 side, and to transmit the signal by radio. The signal reception unit 202 includes a function configured to receive various signals transmitted from the user apparatus 10, and to obtain information of upper layer from the received signal.

The configuration information management unit 203 stores various configuration information to be transmitted to the user apparatus 10. Content of the configuration information is, for example, information of priority of RNTI described so far. Also, the configuration information management unit 203 stores RNTIs held by each user apparatus. The priority notification control unit 204 performs notification of priority of RNTI described in the present embodiment via the signal transmission unit 201.

<Hardware Configuration>

The block diagrams (FIGS. 13 and 14) which are used above to describe the embodiments illustrate blocks in the units of functions. The functional blocks (constituent units) are embodied in an arbitrary combination of hardware and/or software. Means for embodying the functional blocks is not particularly limited. That is, the functional blocks may be embodied by one unit in which a plurality of components are physically and/or logically coupled, or may be embodied by two or more devices which are physically and/or logically separated and which are connected directly and/or indirectly (for example, in a wired and/or wireless manner).

For example, the user apparatus 10 and the base station 20 according to this embodiment may function as computers that perform the processes according to this embodiment. FIG. 15 is a diagram illustrating an example of a hardware configuration of the user apparatus 10 and the base station 20 according to this embodiment. The user apparatus 10 and the base station 20 may be physically configured as a computer device including a processor 1001, a memory 1002, a storage 1003, a communication device 1004, an input device 1005, an output device 1006, and a bus 1007.

In the following description, a word “device” may be referred to as a circuit, a device, a unit, or the like. The hardware configurations of the user apparatus 10 and the base station 20 may include one or more devices indicated by reference numerals 1001 to 1006 in the drawing or may not include some devices thereof.

The functions of the user apparatus 10 and the base station 20 are realized by causing hardware such as the processor 1001 and the memory 1002 to read predetermined software (a program) and causing the processor 1001 to perform calculation and to control communication of the communication device 1004 and reading and/or writing of data in the memory 1002 and the storage 1003.

The processor 1001 controls the computer as a whole, for example, by activating an operating system. The processor 1001 may be constituted by a central processing device (CPU : central processing unit) including an interface with peripherals, a control device, a calculation device, a register, and the like.

The processor 1001 reads a program (program codes), a software module, or data from the storage 1003 and/or the communication deice 1004 to the memory 1002 and performs various processes in accordance therewith. As the program, a program causing a computer to perform at least a part of the operations described above in the embodiment is used. For example, the signal transmission unit 101, the signal reception unit 102, the configuration information managing unit 103 and the sequence selection unit 104 of the user apparatus 10 shown in FIG. 13 may be embodied by a control program which is stored in the memory 1002 and operated by the processor 1001. The signal transmission unit 201, the signal reception unit 202, the configuration information management unit 203 and the priority notification control unit 204 of the base station 20 shown in FIG. 14 may be embodied by a control program which is stored in the memory 1002 and operated by the processor 1001. Various processes described above have been described to be performed by a single processor 1001, but may be simultaneously or sequentially performed by two or more processors 1001. The processor 1001 may be mounted as one or more chips. The program may be transmitted from a network via an electric communication line.

The memory 1002 is a computer-readable recording medium and may be constituted, for example, by at least one of a read only memory (ROM), an erasable programmable ROM (EPROM), an electrically erasable programmable ROM (EEPROM), and a random access memory (RAM). The memory 1002 may be referred to as a register, a cache, or a main memory (a main storage device). The memory 1002 can store a program (program codes), a software module, or the like which can be executed to perform the processes according to the embodiment.

The storage 1003 is a computer-readable recording medium and may be constituted, for example, by at least one of an optical disc such as a compact disc ROM (CD-ROM), a hard disk drive, a flexible disk, a magneto-optical disk (such as a compact disk, a digital versatile disk, or a Blu-ray (registered trademark) disk), a smart card, a flash memory (such as a card, a stick, or a key drive), a floppy (registered trademark) disk, and a magnetic strip. The storage 1003 may be referred to as an auxiliary storage device. Examples of the recording medium may include a database including the memory 1002 and/or the storage 1003, a server, and another appropriate medium.

The communication device 1004 is hardware (a transceiver device) that allows communication between computers via a wired and/or wireless network and is referred to as, for example, a network device, a network controller, a network card, or a communication module. For example, the signal transmission unit 101 and the signal reception unit 102 of the user apparatus 10 may be embodied by the communication device 1004. The signal transmission unit 201 and the signal reception unit 202 of the base station 20 may be embodied by the communication device 1004.

The input device 1005 is an input device (such as a keyboard, a mouse, a microphone, a switch, a button, or a sensor) that receives an input from the outside. The output device 1006 is an output device (such as a display, a speaker, or an LED lamp) that performs outputting to the outside. The input device 1005 and the output device 1006 may be configured as a unified body (such as a touch panel).

The devices such as the processor 1001 and the memory 1002 are connected to each other via the bus 1007 for transmitting and receiving information. The bus 1007 may be constituted by a single bus or may be configured by different buses for the devices.

The user apparatus 10 and the base station 20 may be configured to include hardware such as a microprocessor, a digital signal processor (DSP), an application specific integrated circuit (ASIC), a programmable logic device (PLD), or a field programmable gate array (FPGA), or a part or all of the functional blocks may be embodied by the hardware. For example, the processor 1001 may be implemented by at least one hardware module of these.

(Summary of Embodiments)

As described above, according to the present embodiment, there is provided a communication apparatus for use in a radio communication system, including: a reception unit configured to receive, from another communication apparatus, coded information to which a predetermined identifier is applied, decode the coded information to obtain a predetermined number of sequences that are candidates of a final decoding result, and perform a check by an error detection code using a plurality of identifiers for each of the predetermined number of sequences; and a sequence selection unit configured, if the check by the error detection code succeeds in a plurality of sequences by the reception unit, to select a sequence of the highest likelihood from the plurality of sequences as the final decoding result.

According to the above-mentioned configuration, in a technique in which a communication apparatus selects, based on a check by an error correction code, one sequence from a plurality of sequences obtained by decoding coded information to which a predetermined identifier is applied, it becomes possible that the communication apparatus properly selects one sequence when a plurality of sequences are obtained by the check by the error correction code.

Also, according to the present embodiment, there is provided a communication apparatus for use in a radio communication system, including: a reception unit configured to receive, from another communication apparatus, coded information to which a predetermined identifier is applied, decode the coded information to obtain a predetermined number of sequences that are candidates of a final decoding result, and perform a check by an error detection code using a plurality of identifiers for each of the predetermined number of sequences; and a sequence selection unit configured, if the check by the error detection code succeeds in a plurality of sequences by the reception unit, to select, as the final decoding result, a sequence in which priority of an identifier used when the check by the error detection code succeeds is the highest from the plurality of sequences.

According to the above-mentioned configuration, in a technique in which a communication apparatus selects, based on a check by an error correction code, one sequence from a plurality of sequences obtained by decoding coded information to which a predetermined identifier is applied, it becomes possible that the communication apparatus properly selects one sequence when a plurality of sequences are obtained by the check by the error correction code.

When priorities of identifiers used when the check by the error detection code succeeds are the same among the plurality of sequences, the sequence selection unit may select a sequence of the highest likelihood from the plurality of sequences as the final decoding result. According to this configuration, even when priorities of identifiers are the same, one sequence can be properly selected.

The sequence selection unit may determine an identifier used when the check by the error detection code succeeds for a sequence selected as the final decoding result to be the predetermined identifier applied in the other communication apparatus. According to this configuration, a type of a channel transmitted by the other communication apparatus can be properly determined.

(Complement of Embodiment)

While embodiments of the invention have been described above, the invention disclosed herein is not limited to the embodiments and it will be understood by those skilled in the art that various modifications, corrections, alternatives, substitutions, and the like can be made. While description has been made using specific numerical value examples for the purpose of promoting understanding of the invention, such numerical values are only simple examples and arbitrary appropriate values may be used unless otherwise specified. The sorting of items in the above description is not essential to the invention, details described in two or more items may be combined for use if necessary, or details described in a certain item may be applied to details described in another item (unless incompatible). Boundaries between functional units or processing units in the functional block diagrams cannot be said to be necessarily correspond to boundaries of physical components. Operations of a plurality of functional units may be physically performed by one component, or an operation of one functional unit may be physically performed by a plurality of components. The processing sequences described above may be changed in the order as long as they are not incompatible with each other. For the purpose of convenience of description, while a user apparatus 10 and a base station 20 have been described above with reference to functional block diagrams, such apparatuses may be embodied by hardware, by software, or by combination thereof. Each of software which is executed by a processor of the user apparatus 10 and software which is executed by a processor of the base station 20 in the embodiments of the invention may be stored in an appropriate storage medium such as a random access memory (RAM), a flash memory, a read only memory (ROM), an EPROM, an EEPROM, a register, a hard disk (HDD), a removable disk, a CD-ROM, a database, or a server.

Notification of information is not limited to the aspects/embodiments described in this specification, but may be performed using other methods. For example, the notification of information may be performed physical layer signaling (such as downlink control information (DCI) or uplink control information (UCI)), upper layer signaling (such as radio resource control (RRC) signal, medium access control (MAC) signaling, or broadcast information (master information block (MIB) and system information block (SIB))), other signals, or combinations thereof. The RRC signaling may be referred to as an RRC message and may be, for example, an RRC connection setup message or an RRC connection reconfiguration message.

The aspects/embodiments described in this specification may be applied to systems employing long term evolution (LTE), LTE-advanced (LTE-A), SUPER 3G, IMT-Advanced, 4G, 5G, future radio access (FRA), W-CDMA (registered trademark), GSM (registered trademark), CDMA2000, ultra mobile broadband (UMB), IEEE 802.11 (Wi-Fi), IEEE 802.16 (WiMAX), IEEE 802.20, ultra-wideband (UWB), Bluetooth (registered trademark), or other appropriate systems and/or next-generation systems to which the systems are extended.

The processing sequences, the sequences, flowcharts and the like of the aspects/embodiments described above in this specification may be changed in the order as long as they are not incompatible with each other. For example, in the methods described in this specification, various steps as elements are described in an exemplary order and the methods are not limited to the described order.

Specific operations which are performed by the base station 20 in this specification may be performed by an upper node thereof in some cases. In a network including one or more network nodes including a base station 20, various operations which are performed to communicate with a user apparatus 10 can be apparently performed by the base station 20 and/or network nodes (for example, an MME or an S-GW can be considered but the network nodes are not limited thereto) other than the base station 20. A case in which the number of network nodes other than the base station 20 is one has been described above, but a combination of plural different network nodes (for example, an MME and an S-GW) may be used.

Each aspect/embpdiment described in this specification may be used alone, may be used in combination, or may be switched with implementation thereof.

The user apparatus 10 may also be referred to as a subscriber station, a mobile unit, a subscriber unit, a wireless unit, a remote unit, a mobile device, a wireless device, a wireless communication device, a remote device, a mobile subscriber station, an access terminal, a mobile terminal, a wireless terminal, a remote terminal, a handset, a user agent, a mobile client, a client, or several appropriate terms by those skilled in the art.

The base station 20 may be referred to as an NodeB (NB), an enhanced NodeB (eNB), a base station, or some other appropriate terms by those skilled in the art.

The terms “determining (determining)” and “deciding (determining)” used in this specification may include various types of operations. For example, “determining” and “deciding” may include deeming that to perform judging, calculating, computing, processing, deriving, investigating, looking up (e.g., search in a table, a database, or another data structure), or ascertaining is to perform “determining” or “deciding”. Furthermore, “determining” and “deciding” may include deeming that to perform receiving (e.g., reception of information), transmitting (e.g., transmission of information), input, output, or accessing (e.g., accessing data in memory) is to perform “determining” or “deciding”. Furthermore, “determining” and “deciding” may include deeming that to perform resolving, selecting, choosing, establishing, or comparing is to perform “determining” or “deciding”. Namely, “determining” and “deciding” may include deeming that some operation is to perform “determining” or “deciding”.

An expression “on the basis of ˜” which is used in this specification does not refer to only “on the basis of only ˜,” unless apparently described. In other words, the expression “on the basis of ˜” refers to both “on the basis of only ˜” and “on the basis of at least ˜.”

So long as terms “include” and “including” and modifications thereof are used in this specification or the appended claims, the terms are intended to have a comprehensive meaning similar to a term “comprising.” A term “or” which is used in this specification or the claims is intended not to mean an exclusive or.

In the entire disclosure, for example, when an article such as a, an, or the is added in translation into English, such an article refers to including the plural unless otherwise recognized from the context.

While the invention has been described above in detail, it is apparent to those skilled in the art that the invention is not limited to the embodiments described in the specification. The invention can be carried out as modified and changed embodiments without departing from the concept and scope of the invention which are defined by the appended claims. Accordingly, the description in this specification is made for illustrative description and does not have any restrictive meaning.

This patent application is based upon and claims the benefit of priority of Japanese Patent Application No. 2017-015959 filed on Jan. 31, 2017, and the entire contents of Japanese Patent Application No. 2017-015959 are incorporated herein by reference.

### LIST OF REFERENCE SYMBOLS

10 user apparatus
101 signal transmission unit
102 signal reception unit
103 configuration information management unit
104 sequence selection unit
20 base station
201 signal transmission unit
202 signal reception unit
203 configuration information management unit
204 priority notification control unit
1001 processor
1002 memory
1003 storage
1004 communication device
1005 input device
1006 output device

1. A communication apparatus for use in a radio communication system, comprising:
a reception unit configured to receive, from another communication apparatus, coded information to which a predetermined identifier is applied, decode the coded information to obtain a predetermined number of sequences that are candidates of a final decoding result, and perform a check by an error detection code using a plurality of identifiers for each of the predetermined number of sequences; and
a sequence selection unit configured, if the check by the error detection code succeeds in a plurality of sequences by the reception unit, to select a sequence of the highest likelihood from the plurality of sequences as the final decoding result.

2. A communication apparatus for use in a radio communication system, comprising:
a reception unit configured to receive, from another communication apparatus, coded information to which a predetermined identifier is applied, decode the coded information to obtain a predetermined number of sequences that are candidates of a final decoding result, and perform a check by an error detection code using a plurality of identifiers for each of the predetermined number of sequences; and
a sequence selection unit configured, if the check by the error detection code succeeds in a plurality of sequences by the reception unit, to select, as the final decoding result, a sequence in which priority of an identifier used when the check by the error detection code succeeds is the highest from the plurality of sequences.

3. The communication apparatus as claimed in claim 2, wherein, when priorities of identifiers used when the check by the error detection code succeeds are the same among the plurality of sequences, the sequence selection unit selects a sequence of the highest likelihood from the plurality of sequences as the final decoding result.

4. The communication apparatus as claimed in claim 1, wherein the sequence selection unit determines an identifier used when the check by the error detection code succeeds for a sequence selected as the final decoding result to be the predetermined identifier applied in the other communication apparatus.

5. A sequence selection method executed by a communication apparatus for use in a radio communication system, comprising:
a reception step of receiving, from another communication apparatus, coded information to which a predetermined identifier is applied, decoding the coded information to obtain a predetermined number of sequences that are candidates of a final decoding result, and performing a check by an error detection code using a plurality of identifiers for each of the predetermined number of sequences; and
a sequence selection step of, if the check by the error detection code succeeds in a plurality of sequences by the reception step, selecting a sequence of the highest likelihood from the plurality of sequences as the final decoding result.

6. A sequence selection method executed by a communication apparatus for use in a radio communication system, comprising:
a reception step of receiving, from another communication apparatus, coded information to which a predetermined identifier is applied, decoding the coded information to obtain a predetermined number of sequences that are candidates of a final decoding result, and performing a check by an error detection code using a plurality of identifiers for each of the predetermined number of sequences; and
a sequence selection step of, if the check by the error detection code succeeds in a plurality of sequences by the reception step, selecting, as the final decoding result, a sequence in which priority of an identifier used when the check by the error detection code succeeds is the highest from the plurality of sequences.

7. The communication apparatus as claimed in claim 2, wherein the sequence selection unit determines an identifier used when the check by the error detection code succeeds for a sequence selected as the final decoding result to be the predetermined identifier applied in the other communication apparatus.

8. The communication apparatus as claimed in claim 3, wherein the sequence selection unit determines an identifier used when the check by the error detection code succeeds for a sequence selected as the final decoding result to be the predetermined identifier applied in the other communication apparatus.
